(19) United States
(12) Patent Application Publication
(10) Pub. No.: US 2013/0234110 A1
(43) Pub. Date: Sep. 12, 2013

(54) GALLIUM NITRIDE BASED COMPOUND SEMICONDUCTOR LIGHT-EMITTING ELEMENT AND METHOD FOR FABRICATING THE SAME

(71) Applicant: PANASONIC CORPORATION, Osaka (JP)

(72) Inventors: Ryou KATO, Osaka (JP); Shunji YOSHIDA, Osaka (JP); Songbaek CHOE, Osaka (JP); Toshiya YOKOGAWA, Nara (JP)

(73) Assignee: Panasonic Corporation, Osaka (JP)

(21) Appl. No.: 13/868,195

(22) Filed: Apr. 23, 2013

Related U.S. Application Data
(63) Continuation of application No. PCT/JP2012/002291, filed on Apr. 2, 2012.

(30) Foreign Application Priority Data
Apr. 12, 2011 (JP) 2011-087949

(51) Int. Cl. H01L 33/14; H01L 33/06

(52) U.S. Cl. CPC H01L 33/145; H01L 33/06
USPC 257/13; 438/47

(57) ABSTRACT

A gallium nitride based compound semiconductor light-emitting element according to an embodiment of the present disclosure includes: an n-type gallium nitride based compound semiconductor layer; a p-type gallium nitride based compound semiconductor layer; and an active layer which is arranged between the n- and p-type gallium nitride based compound semiconductor layers. The active layer and the p-type gallium nitride based compound semiconductor layer are m-plane semiconductor layers. The p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium.

This is a continuation of International Application No. PCT/JP2012/002291, with an international filing date of Apr. 2, 2012, which claims priority of Japanese Patent Application No. 2011-087949, filed on Apr. 12, 2011, the contents of which are hereby incorporated by reference.

### BACKGROUND

1. Technical Field

The present application relates to a gallium nitride based compound semiconductor light-emitting element and a method for fabricating such an element.

2. Description of the Related Art

A nitride semiconductor including nitrogen (N) as a Group V element is a prime candidate for a material to make a short-wave light-emitting element, because its bandgap is sufficiently wide. Among other things, gallium nitride-based compound semiconductors (which will be referred to herein as “GaN-based semiconductors”) have been researched and developed particularly extensively. As a result, blue-ray-emitting light-emitting diodes (LEDs), green-ray-emitting LEDs and semiconductor laser diodes made of GaN-based semiconductors have already been used in actual products.

A gallium nitride-based compound semiconductor has a wurtzite crystal structure. FIG. 1 schematically illustrates a unit cell of GaN. In an AlₐGa_{b}In_{c}N (where 0≦a, b, c≦1 and a+b+c=1) semiconductor crystal, some of the Ga atoms shown in FIG. 1 may be replaced with Al and/or In atoms.

FIG. 2 shows four primitive vectors a₁, a₂, a₃ and c, which are generally used to represent planes of a wurtzite crystal structure with four indices (i.e., hexagonal indices). The primitive vector c runs in the [0001] direction, which is called a “c axis”. A plane that intersects with the c axis at right angles is called either a “c plane” or a “(0001) plane”. It should be noted that the “c axis” and the “c plane” are sometimes referred to as “C axis” and “C plane”.

As shown in FIG. 3, the wurtzite crystal structure has other representative crystallographic plane orientations, not just the c plane. Portions (a), (b), (c) and (d) of FIG. 3 illustrate a (0001) plane, a (10-10) plane, a (11-20) plane, and a (10-12) plane, respectively. In this case, “−” attached on the left-hand side of a Miller-Bravais index in the parentheses means a “bar” (a negative direction index). The (0001), (10-10), (11-20) and (10-12) planes are c, m, a and r planes, respectively. The m and a planes are “non-polar planes” that are parallel to the c axis but the r plane is a “semi-polar plane”. It should be noted that the m plane is a generic term that collectively refers to a family of (10-10), (−1010), (1-100), (−1100), (01-10) and (0-110) planes.

Light-emitting elements that use gallium nitride based compound semiconductors have long been made by “c-plane growth” process. In this description, the “X-plane growth” means epitaxial growth that is produced perpendicularly to the X plane (where X==c, m, a or r, for example) of a hexagonal wurtzite structure. As for the X-plane growth, the X plane will be sometimes referred to herein as a “growing plane”. Furthermore, a layer of semiconductor crystals that have been formed as a result of the X-plane growth will be sometimes referred to herein as an “X-plane semiconductor layer”.

If a light-emitting element is fabricated as a semiconductor multilayer structure by c-plane growth process, then intense internal electric polarization will be produced perpendicularly to the c plane (i.e., in the c axis direction), because the c plane is a polar plane. Specifically, that electric polarization is produced, because on the c-plane, Ga and N atoms are located at different positions with respect to the c axis. Once such electric polarization is produced in a light-emitting layer (i.e., in an active layer), the quantum confinement Stark effect of carriers will be generated. As a result, the probability of radiative recombination of carriers in the light-emitting layer decreases, thus decreasing the luminous efficiency as well.

To overcome such a problem, a lot of people have recently been making every effort to grow gallium nitride based compound semiconductors on a non-polar plane such as an m or a plane or on a semi-polar plane such as an r plane. If a non-polar plane can be selected as a growing plane, then no electric polarization will be produced in the thickness direction of the light-emitting layer (i.e., in the crystal growing direction). As a result, no quantum confinement Stark effect will be generated, either. Thus, a light-emitting element having potentially high efficiency can be fabricated. The same can be said even if a semi-polar plane is selected as a growing plane. That is to say, the influence of the quantum confinement Stark effect can be reduced significantly in that case, too.

FIG. 4A schematically illustrates the crystal structure of a nitride-based semiconductor, of which the principal surface (growing plane) is an m plane, as viewed on a cross section thereof that intersects with the principal surface of the substrate at right angles. The Ga atoms and nitrogen atoms are on the same atomic plane that is parallel to the m plane. For that reason, no electric polarization will be produced perpendicularly to the m plane. It should be noted that In and Al atoms that have been added are located at Ga sites to replace Ga atoms. Even when at least some of the Ga atoms are replaced with In and Al atoms, no electric polarization will be produced perpendicularly to the m plane, either.

The crystal structure of a nitride-based semiconductor, of which the principal surface is a c plane, as viewed on a cross section thereof that intersects with the principal surface of the substrate at right angles is illustrated schematically in FIG. 4B just for your reference. In this case, Ga atoms and nitrogen atoms are not present on the same atomic plane that is parallel to the c plane. For this reason, the electric polarization will be produced perpendicularly to the c plane. A c-plane GaN-based substrate is generally used as a substrate to grow GaN based semiconductor crystals thereon. As the positions of the Ga (or In) atomic layer and nitrogen atomic layer, which are parallel to the c plane, slightly shift from each other in the c-axis direction, electric polarization is produced in the c-axis direction.

### SUMMARY

The prior art technique needs further improvement in view of the reliability and electric characteristics.

One non-limiting, and exemplary embodiment provides a technique to improve the reliability and electric characteristics.

In one general aspect, a gallium nitride based compound semiconductor light-emitting element disclosed herein includes: an n-type gallium nitride based compound semiconductor layer; a p-type gallium nitride based compound semiconductor layer; an active layer which is arranged between the n- and p-type gallium nitride based compound semiconductor layers; and a p-type AlₓGa_{y}N (where 0<x≦1 and 0≦y<1) electron blocking layer which is arranged between the p-type gallium nitride based compound semiconductor layer and the active layer. The active layer and the p-type gallium nitride based compound semiconductor layer are m-plane semiconductor layers. The p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium. The p-type AlₓGa_{y}N (where 0<x≦1 and 0≦y<1) electron blocking layer is adjacent to the p-type gallium nitride based compound semiconductor layer. The p-type AlₓGa_{y}N (where 0<x≦1 and 0≦y<1) electron blocking layer has a higher oxygen concentration than the p-type gallium nitride based compound semiconductor layer.

According to the above aspect, diffusion of hydrogen from a p-type layer into an active layer, which will ordinarily often occur in an m-plane semiconductor multilayer structure, can be reduced. In addition, the p-type layer can maintain good electric characteristics as well. Consequently, according to the above aspect, a light-emitting element can be fabricated so as to have its reliability and electric characteristic improved.

These general and specific aspects may be implemented using a method. Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1 is a perspective view schematically illustrating a unit cell of GaN.

FIG. 2 is a perspective view showing the four primitive vectors a₁, a₂, a₃ and c of a wurtzite crystal structure.

FIGS. 3A through 3D are schematic representations illustrating representative crystallographic plane orientations of a hexagonal wurtzite structure.

FIG. 4A illustrates the crystal structure of an m plane.

FIG. 4B illustrates the crystal structure of a c plane.

FIGS. 5A and 5B show the results of a SIMS analysis which was carried out to examine how differently hydrogen would diffuse from a p-type layer depending on whether the growing plane is an m plane or a c plane.

FIGS. 6A and 6B show the results of a SIMS analysis which was carried out to examine how a difference in oxygen concentration would affect the diffusion of hydrogen.

FIG. 7 is a graph showing how the diffusion penetration length of hydrogen changes with the concentration of oxygen in a p-type layer having an Mg concentration of 1.2×10¹⁹ cm⁻³.

FIG. 8 is a graph showing how the relation between the Mg and oxygen concentrations of a p-type layer changes with the growing condition.

FIG. 9 is a graph classifying the influence of the Mg and oxygen concentrations of a p-type layer on the characteristic of an element.

FIG. 10 is a graph classifying the influence of the hydrogen and oxygen concentrations of a p-type layer on the characteristic of an element.

FIG. 11 is a graph showing how the hydrogen concentration of a p-type layer changes before and after an annealing process.

FIG. 12 is a schematic cross-sectional view illustrating a configuration for a gallium nitride based compound semiconductor light-emitting element according to an exemplary embodiment.

FIG. 13 is a cross-sectional view illustrating a light source according to another exemplary embodiment.

FIGS. 14A and 14B Show the results of a SIMS analysis according to an exemplary embodiment.

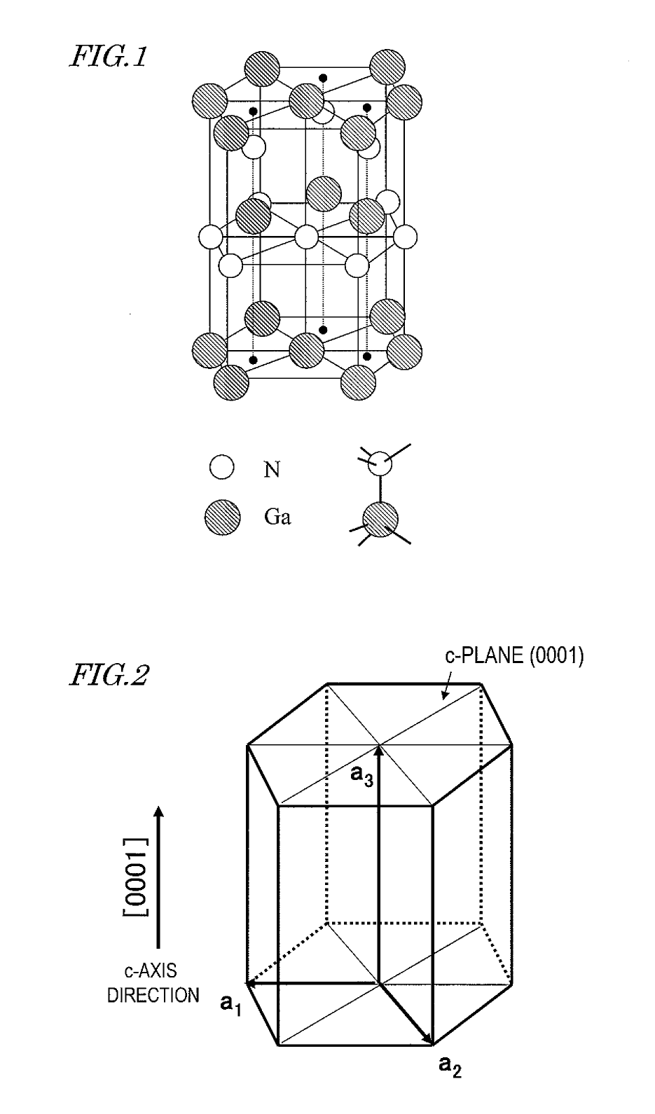

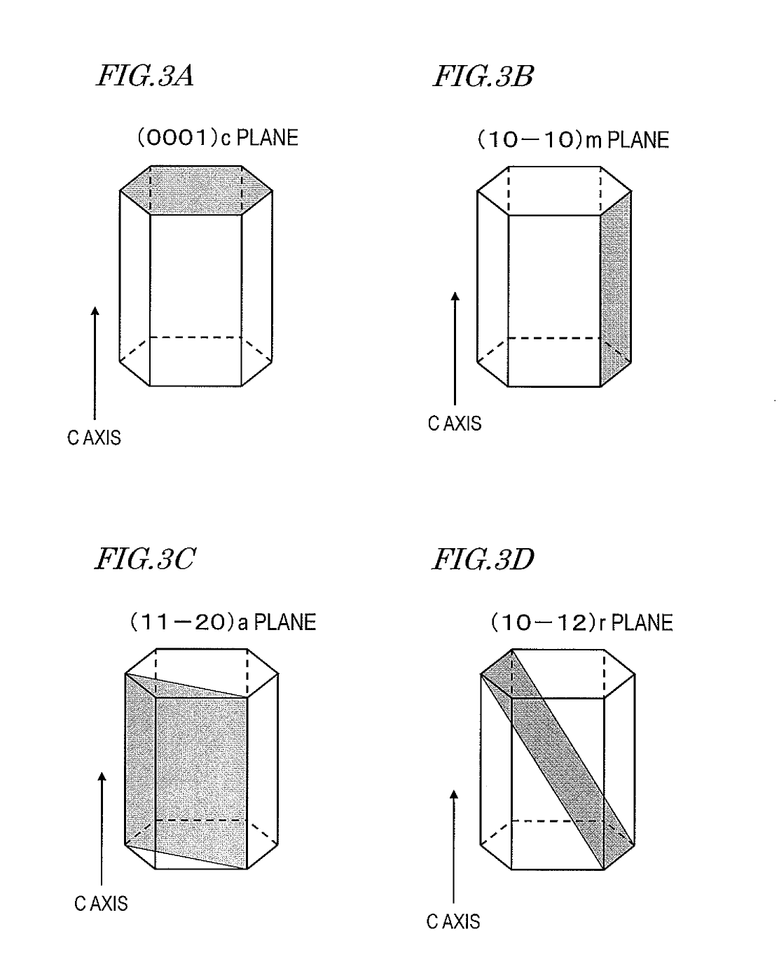

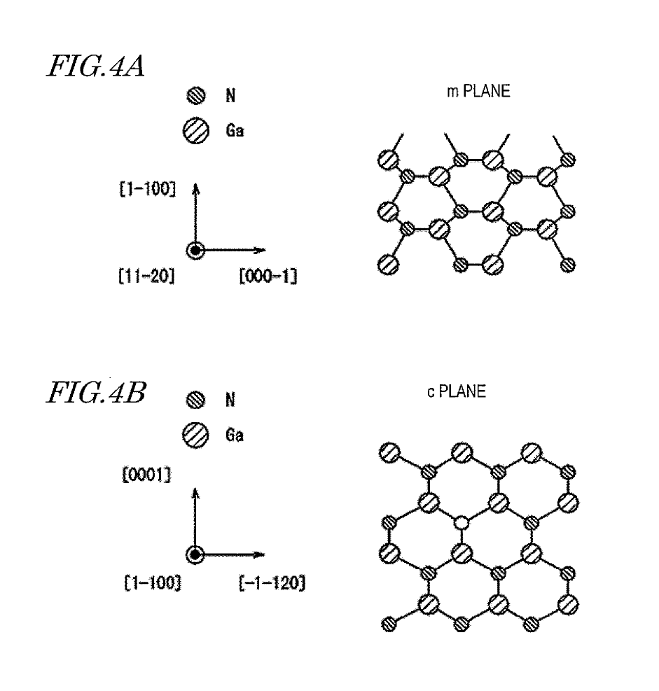

### DETAILED DESCRIPTION

First of all, it will be described to what point the present inventors paid special attention in the present disclosure.

Generally speaking, when grown by some vapor phase deposition such as an MOCVD (metalorganic chemical vapor deposition), crystals of a gallium nitride based compound semiconductor light-emitting element are likely to include oxygen, carbon, hydrogen and other impurities unintentionally. It is possible to reduce those impurities to a certain degree depending on the crystal growing condition but it is very difficult to eliminate them altogether.

Ordinarily, those impurities will be included at mutually different concentrations in respective layers that form a light-emitting element. For example, oxygen will enter particularly easily a layer including aluminum (Al). Meanwhile, hydrogen will enter a p-type layer, to which magnesium (Mg) has been added as a p-type dopant, and will have almost as high a concentration as Mg there. Hydrogen present in such a semiconductor layer would form a bond with Mg. This is because an n-type layer to which no Mg is added has a lower hydrogen concentration than a p-type layer.

A gallium nitride based compound semiconductor is controlled so that the concentration of Mg in a p-type layer falls within the range of 1×10¹⁸ cm⁻³ to 1×10²⁰ cm⁻³. If the Mg concentration were too low, the carrier concentration of the p-type layer would be too low, too. Conversely, if the Mg concentration were too high, then the p-type layer would have lower carrier mobility. As can be seen, if the Mg concentration fell outside of an appropriate range, the resistivity of the p-type layer would decrease. As almost as many hydrogen atoms as Mg atoms enter a p-type layer, the p-type layer will have a hydrogen concentration of 1×10¹⁸ cm⁻³ to 1×10²⁰ cm⁻³.

A lot of impurities that have entered will decrease crystallinity. For example, oxygen that has entered an active layer (light-emitting layer) will be a non-radiative center that will decrease the luminous efficiency of the element. In addition, the hydrogen that has entered the active layer will be a factor in decreased reliability, too. Thus, by setting the concentration of the impurity hydrogen that has entered the active layer to be 2.0×10¹⁷ cm⁻³ or less, the light-emitting element can ensure a sufficient degree of reliability.

In fabricating a gallium nitride based compound semiconductor light-emitting element, hydrogen that has bonded to Mg as a p-type dopant is usually detached out of crystals by performing an annealing process (as a heat treatment), for example, after semiconductor crystals have grown. If the annealing process is carried out, the concentration of the impurity hydrogen inside the crystals decreases to approximately one tenth. That is why by decreasing the concentration of hydrogen to be included in the active layer right after a semiconductor multilayer structure has been formed and before the annealing process is carried out to 2.0×10¹⁸ cm⁻³ or less, the concentration of hydrogen included in the active layer after the annealing process has been carried out can be decreased to 2.0×10¹⁷ cm⁻³ or less.

However, even if the concentration of hydrogen in the active layer can be low enough before the annealing process but if hydrogen that has entered a p- or n-type layer that is adjacent to the active layer has a high concentration there, then the reliability of the light-emitting element may still decrease. The reason is that in such a situation, the hydrogen may diffuse and reach the active layer after all while a patterning process is performed to form an electrode after crystals have grown or while the element is being driven. Particularly, even if subjected to the annealing process, hydrogen that has been entered an Mg-doped p-type layer often has as high a concentration as 2.0×10¹⁷ cm⁻³ or more, which is usually higher than the concentration of hydrogen to enter the active layer. For that reason, the hydrogen may diffuse from the p-type layer and reach the active layer.

Japanese Laid-Open Patent Publication No. 2001-298214 presents the problem that “hydrogen remaining in a p-type layer would not only prevent a p-type dopant from being activated but also shorten the life of the element fabricated, because that residual hydrogen would diffuse gradually and deteriorate the active layer while the element is energized” and says that that problem can be overcome “if the step of forming the p-type layer includes the step of growing a nitride semiconductor material in an atmosphere that does not include hydrogen gas”. However, the present inventors discovered via experiments that hydrogen would also enter a p-type layer formed by such a method and that the resistivity would be very high unless hydrogen is detached out of the crystals by performing an annealing process.

The present inventors also discovered that in an m-plane-growing semiconductor, hydrogen would diffuse noticeably from a p-type layer toward an active layer. Such hydrogen diffusion was never observed in a c-plane semiconductor. Hereinafter, this hydrogen diffusion will be described in detail with reference to the accompanying drawings.

The results of the experiments the present inventors carried out revealed that hydrogen also diffused from the p-type layer toward the active layer while crystals were growing, too, and that the diffusion of hydrogen from the p-type layer toward the active layer occurred sometimes easily, and sometimes not, depending on the growing plane of the semiconductor layer. Specifically, if the growing plane is a (0001) c plane which is a typical crystal growing plane when a light-emitting element is made of a gallium nitride based compound semiconductor, the diffusion of hydrogen from the p-type layer toward the active layer tends to occur less easily. On the other hand, in a light-emitting element of which the growing plane is an m plane, hydrogen in the p-type layer tends to diffuse more easily.

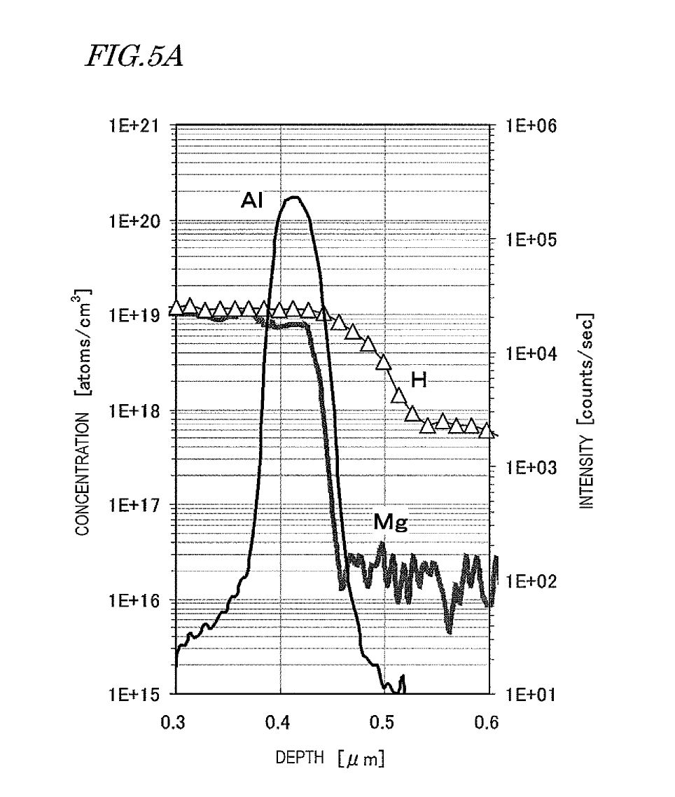

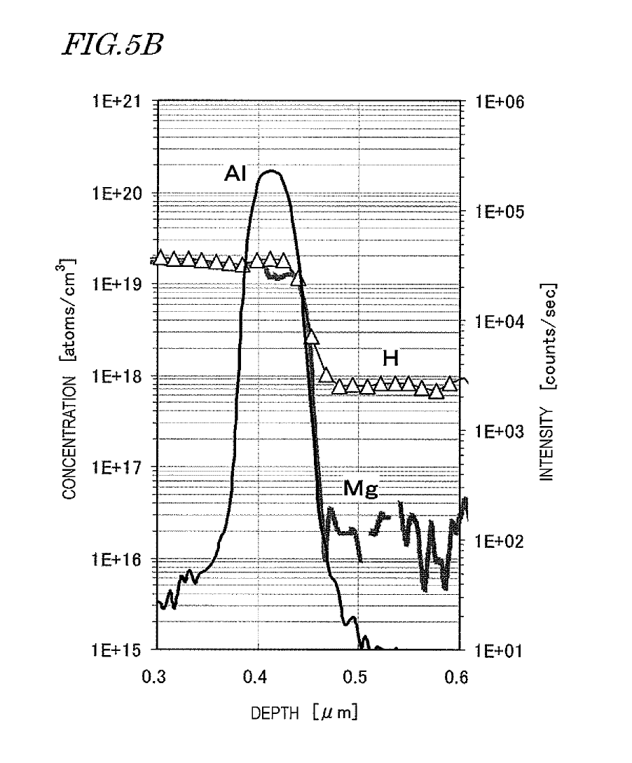

FIG. 5A shows the results of a SIMS (secondary ion mass spectrometry) analysis that was carried out on an m-plane sample that had been formed on an m-plane GaN substrate. On the other hand, FIG. 5B shows the results of a SIMS analysis that was carried out on a c-plane sample that had been formed on a c-plane GaN substrate.

These samples were formed at the same time by depositing an n-type layer and a p-type layer in this order on a substrate. As the p-type layer, an Al_{0.2}Ga_{0.8}N layer including Al was deposited to a thickness of about 20 nm in an early stage of the growth. Thus, the decision can be made that a point with a peak Al concentration should be a point where Mg started to be introduced as a p-type dopant. In FIGS. 5A and 5B, the black bold curve, grey bold curve and open triangle (Δ) curve represent the concentration profiles in the depth direction of Al, Mg and hydrogen (H), respectively. The concentration of Al is indicated as the detection intensity (counts/sec) on the axis of ordinates on the right-hand side of this drawing, while the concentrations of Mg and H are indicated as the concentrations (atoms/cm³) on the axis of ordinates on the left-hand side of this drawing. On the other hand, the abscissa of this graph represents the depth as measured from the surface of the sample. It should be noted that the ordinates “1.0E+18” and “1.0E+19” mean “1.0×10¹⁸” and “1.0×10¹⁹”, respectively. That is to say, “1.0E+X” means “1.0×10^{X}”. The same notation will apply to the other graphs, too.

According to FIGS. 5A and 5B, the concentrations of hydrogen that entered the p-type layer were 1.0×10¹⁹ cm⁻³ in the m-plane sample and 1.8×10¹⁹ cm⁻³ in the c-plane sample. That is to say, the c-plane growth resulted in a higher hydrogen concentration in the p-type layer than the m-plane growth did. However, the penetration distance of hydrogen from the p-type layer to the active layer is much longer in the m-plane sample than in the c-plane sample.

In this example, the peak point of Al is supposed to be a point where Mg started to be doped (i.e., a point where the p-type layer started to be deposited) and the length as measured from that peak point to a depth at which the concentration of hydrogen decreases to 2.0×10¹⁸ cm⁻³ is defined herein to be the “penetration length”. In the m-plane sample, the penetration length of hydrogen atoms was approximately 100 nm. On the other hand, in the c-plane sample, the penetration length was only 40 nm, which is less than a half of that of the m-plane sample.

The results shown in FIGS. 5A and 5B were obtained by analyzing samples that were not subjected to annealing or any other treatment after the semiconductor multilayer structure had been formed. That is to say, the results shown in FIGS. 5A and 5B indicate that hydrogen already started to diffuse from the p-type layer toward the active layer while crystals were still growing. Such diffusion of hydrogen from the p-type layer toward the active layer occurs not only during a metallization process to form an electrode after crystals have grown and while the element is being driven but also while the crystals are still growing as well.

As can be seen, if a light-emitting element is fabricated using a non-polar (10-10) m plane as a growing plane, such a phenomenon that the impurity hydrogen that has entered the p-type layer would diffuse and reach the active layer to significantly decrease the reliability of the element arises as a serious problem, even though such a problem has hardly occurred if a light-emitting element is fabricated using a (0001) c plane as a growing plane as in a typical traditional manufacturing process.

However, if a gallium nitride based compound semiconductor light-emitting element is fabricated by a method according to an embodiment of the present disclosure, such diffusion of hydrogen toward the active layer that would otherwise occur while crystals are still growing can be suppressed. In addition, the diffusion of hydrogen from the p-type layer to the active layer during the metallization process to form an electrode after the crystals have grown and while the element is being driven can be suppressed as well. That is to say, by reducing the concentration of hydrogen to enter the active layer, the deterioration of the active layer can be minimized and the reliability of the light-emitting element can be increased.

As described above, in a gallium nitride based compound semiconductor that has been made using an m plane as a growing plane, hydrogen included as an impurity in the p-type layer is particularly likely to diffuse and reach the active layer while crystals are growing. The hydrogen would also diffuse and reach the active layer easily even during the metallization process to form an electrode after crystals have grown or while the element is being driven.

Hydrogen would bond to Mg as a p-type dopant and would enter crystals unintentionally. That is why as long as an element is fabricated by the MOCVD process, it is difficult to prevent hydrogen from entering the p-type layer. For that reason, some special measure should be taken to prevent the hydrogen that has entered the p-type layer from diffusing and reaching the active layer. One measure may be to provide a spacer layer including no dopants at all between the p-type layer and the active layer by estimating the diffusion distance in advance. That is to say, such a measure is taken just for the purpose of preventing the diffusing hydrogen from reaching the active layer without trying to prevent the hydrogen's diffusion itself. Such a spacer layer typically has a thickness of 100 nm or more. If the spacer layer were too thick, however, the element's drive voltage should be raised. For that reason, it is recommended that the thickness of the spacer layer be limited to 100 nm or less.

As a result of an extensive research, the present inventors discovered that to prevent hydrogen from diffusing, it would be effective to allow a predetermined percentage of oxygen to enter the p-type layer. Since oxygen becomes an n-type dopant, normally oxygen should be prohibited from entering the p-type layer. Contrary to such a common belief, however, such an intentional addition of oxygen to the p-type layer turned out to be effective in preventing hydrogen from diffusing.

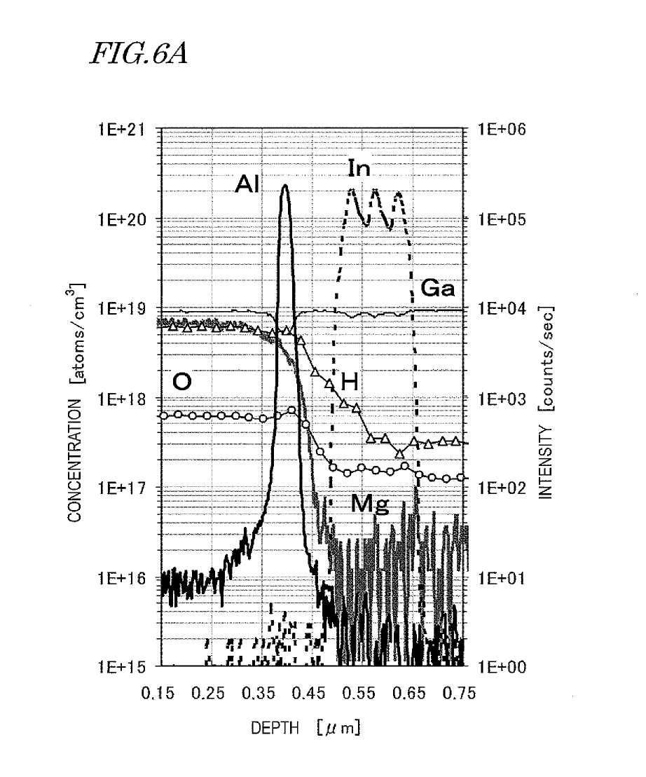

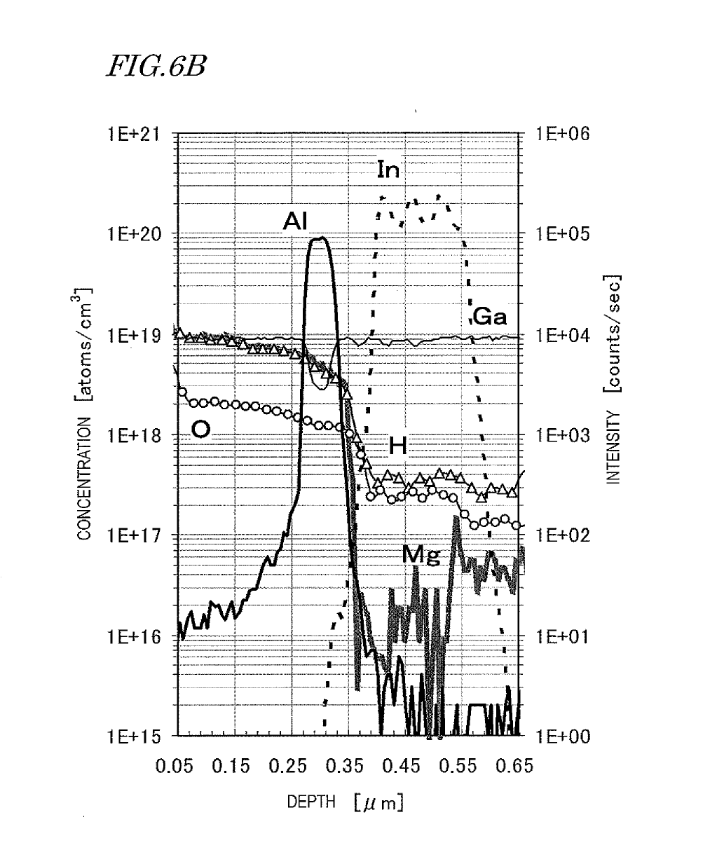

FIGS. 6A and 6B show the results of a SIMS analysis that was carried out on Samples A and B that had been grown on an m-plane GaN substrate under mutually different conditions. In each of these Samples A and B, an n-type layer, an active layer (having a structure in which InGaN well layers and GaN barrier layers had been stacked alternately in three cycles), an undoped GaN spacer layer (having a thickness of 80 nm) and a p-type layer were stacked in this order on the substrate. In the p-type layer, an Al_{0.2}Ga_{0.8}N layer was deposited to a thickness of approximately 20 nm in an early stage of the crystal growing process. Thus, the decision can be made that a point with a peak Al concentration should be a point where Mg started to be introduced as a p-type dopant. These Samples A and B had just had their element structure completed and had not been subjected to annealing yet.

In FIGS. 6A and 6B, the fine curve, bold curve, dashed curve, grey bold curve, open triangle (Δ) curve and open circle (◯) curve represent the respective concentration profiles in the depth direction of Ga, Al, In, Mg, hydrogen (H) and oxygen (O). The concentrations of Ga, Al and In are represented by the detection intensity (counts/sec) on the axis of ordinates on the right-hand side of this drawing, while Mg, H and O are represented by the concentration (atoms/cm³) on the axis of ordinates on the left-hand side of this drawing.

The p-type layer of Sample A shown in FIG. 6A had an Mg concentration of 6.0×10¹⁸ to 7.0×10¹⁸ cm⁻³ and that of Sample B shown in FIG. 6B had an Mg concentration of 7.0×10¹⁸ to 9.0×10¹⁸ cm⁻³. Thus, it can be said that the respective p-type layers of these samples had approximately the same Mg concentration. The concentration of hydrogen in their p-type layer was almost as high as its Mg concentration, and was 6.0×10¹⁸ to 7.0×10¹⁸ cm⁻³ in Sample A and 7.0×10¹⁸ to 9.0×10¹⁸ cm⁻³ in Sample B.

However, the respective p-type layers of Samples A and B grew under mutually different conditions, and therefore, had different oxygen concentrations. Specifically, the p-type layer of Sample A had an oxygen concentration of 6.0×10¹⁷ cm⁻³ while the p-type layer of Sample B had an oxygen concentration of 2.0×10¹⁸ cm⁻³. It will be described later how to control the oxygen concentration.

Samples A and B had quite different hydrogen distributions. Specifically, in Sample A, of which the p-type layer had a low oxygen concentration, hydrogen had diffused a lot toward the undoped GaN spacer layer, and the penetration length from the Al peak point to a point where the hydrogen concentration decreased to 2.0×10¹⁸ cm⁻³ was approximately 45 nm. That is to say, this result indicates that to prevent the impurity hydrogen from diffusing from the p-type layer and reaching the active layer, the active layer should be located at a distance of at least approximately 45 nm from the p-type layer. In Sample B, on the other hand, the penetration length of hydrogen was less than 20 nm, which means that the diffusion of hydrogen was suppressed significantly.

Consequently, even if no spacer layer is provided between the p-type layer and the active layer, it is still possible to prevent the diffusing hydrogen from reaching the active layer. Thus, it can be seen that even if two p-type layers include Mg at substantially the same concentrations but if their oxygen concentrations are different, then hydrogen will diffuse differently in those two layers.

It is not quite clear exactly how and why the diffusion of hydrogen could be suppressed in the p-type layer having the higher oxygen concentration. There is a possibility that a hydrogen-oxygen bond would have been produced to bind the hydrogen and prevent it from moving freely inside the crystals.

An appropriate concentration of oxygen to be added to the p-type layer is determined by the concentration of hydrogen that has entered the p-type layer (i.e., the relative concentration of hydrogen with respect to that of Mg). The present inventors discovered via experiments that to reduce the diffusion penetration length effectively to 100 nm or less to the point that the hydrogen concentration decreased to 2.0×10¹⁸ cm⁻³, the concentration of oxygen in the p-type layer should be at least 5% of the concentration of Mg also included in the same p-type layer.

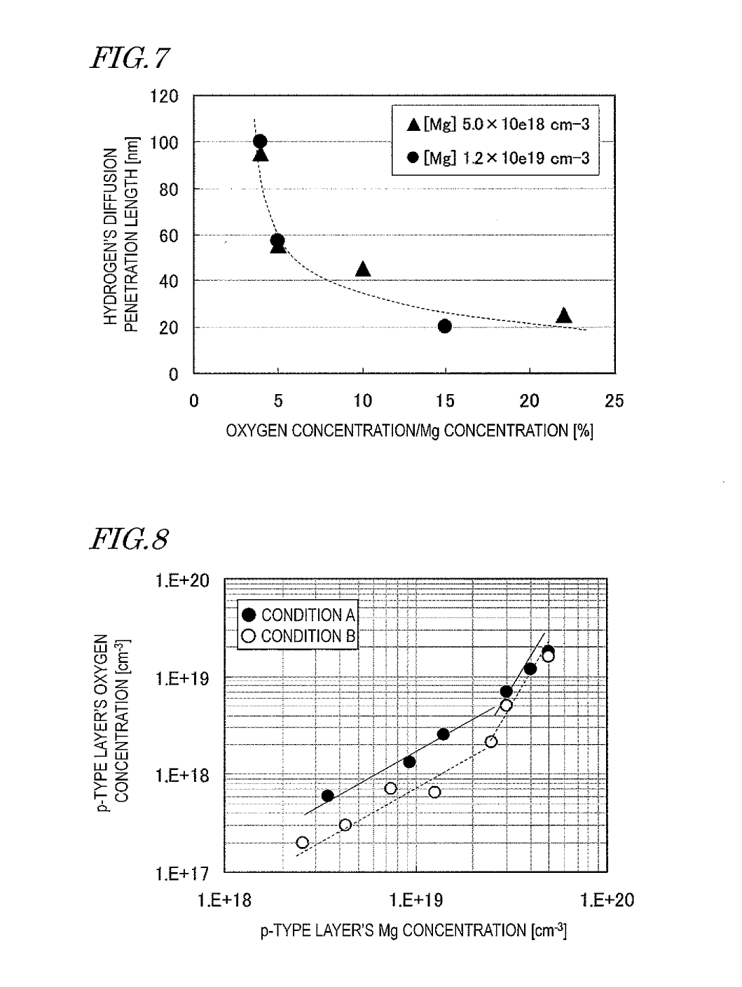

FIG. 7 is a graph showing how the diffusion penetration length of hydrogen changed according to the concentration of oxygen that was added to an m-plane-growing p-type layer having an Mg concentration of 4.0×10¹⁸ to 6.0×10¹⁸ cm⁻³ (having an average of 5.0×10¹⁸ cm⁻³) and to an m-plane-growing p-type layer having an Mg concentration of 1.1×10¹⁹ to 1.3×10¹⁹ cm⁻³ (having an average of 1.2×10¹⁹ cm⁻³). The penetration lengths of hydrogen were estimated based on the distributions of hydrogen that had been obtained by making a SIMS analysis on samples in which the p-type layer had just been deposited without subjecting the samples to annealing or any other treatment,

The following Table 1 summarizes Mg concentrations, ratios of oxygen concentrations to the Mg concentrations, and penetration lengths of hydrogen based on the data shown in FIG. 7.

TABLE 1

| | O₂—Mg concentration ratio | | | | |
|---|---|---|---|---|---|
| Mg concentration | 4% | 5% | 10% | 15% | 22% |
| 5.0 × 10¹⁸ cm⁻³ | 95 nm | 55 nm | 45 nm | — | 25 nm |
| 1.2 × 10¹⁹ cm⁻³ | 100 nm | 57 nm | — | 20 nm | — |

As can be seen from FIG. 7, if the oxygen concentration in the p-type layer was 5% or more of the Mg concentration, the penetration length decreased steeply, no matter how high or low the Mg concentration might be. The oxygen concentration of an m-plane-growing p-type layer deposited by a normal process is typically less than 5% of its Mg concentration. If oxygen was included so that the ratio of oxygen concentration to the Mg concentration was 4%, the penetration length of hydrogen was approximately 100 nm, which was almost twice as long as the penetration length in a situation where oxygen was included at a concentration ratio of 5%, at which the effect of suppressing the hydrogen diffusion started to manifest itself. That is why if the ratio of the concentration of oxygen included in the p-type layer to the Mg concentration is 5% or more, the thickness of the undoped GaN spacer layer to be inserted between the p-type layer and the active layer can be 100 nm or less almost without fail.

However, if the oxygen concentration of the p-type layer were too high, then the electrical characteristic of the p-type layer itself would deteriorate. Oxygen works as an n-type dopant. That is why if the oxygen concentration of the p-type layer were too high, Mg as a p-type dopant would decrease eventually. To make the element fabricated function as a light-emitting element, the resistivity of the p-type layer is suitably 2.0 Ωcm or less. The present inventors discovered via experiments that if the concentration of oxygen that entered the p-type layer was 15% or more of its Mg concentration, the resistivity exceeded 2.0 Ωcm.

For that reason, the oxygen concentration of the p-type layer is suitably 5% to 15% of the Mg concentration. In a situation where oxygen and Mg are both included in the p-type layer, if the oxygen-Mg concentration ratio falls within this range, the electrical characteristic of the p-type layer can be kept good enough with the diffusion of hydrogen from the p-type layer toward the active layer suppressed. It should be noted that to make the p-type layer have a sufficient carrier concentration, the Mg concentration is suitably 2.0×10¹⁸ cm⁻³ or more, irrespective of the oxygen concentration of the p-type layer.

A gallium nitride based compound semiconductor light-emitting element according to an embodiment of the present disclosure includes: an n-type gallium nitride based compound semiconductor layer; a p-type gallium nitride based compound semiconductor layer; an active layer which is arranged between the n- and p-type gallium nitride based compound semiconductor layers; and a p-type AlₓGa_{y}N (where 0<x≦1 and 0≦y<1) electron blocking layer which is arranged between the p-type gallium nitride based compound semiconductor layer and the active layer. The active layer and the p-type gallium nitride based compound semiconductor layer are m-plane semiconductor layers. And the p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium. The p-type AlₓGa_{y}N (where 0<x≦1 and 0≦y<1) electron blocking layer is adjacent to the p-type gallium nitride based compound semiconductor layer. The p-type AlₓGa_{y}N (where 0<x≦1 and 0≦y<1) electron blocking layer has a higher oxygen concentration than the p-type gallium nitride based compound semiconductor layer.

In one embodiment, the p-type gallium nitride based compound semiconductor layer further includes hydrogen at a concentration of 2.0×10¹⁷ cm⁻³ to 2.5×10¹⁸ cm⁻³.

In this particular embodiment, in the p-type gallium nitride based compound semiconductor layer, the concentration of the oxygen included is 60% to 200% of the concentration of the hydrogen included.

In another embodiment, the gallium nitride based compound semiconductor light-emitting element further includes an undoped spacer layer which is arranged between the active layer and the p-type gallium nitride based compound semiconductor layer and which has a thickness of 100 nm or less.

In still another embodiment, the active layer has a multiple quantum well structure.

In yet another embodiment, the gallium nitride based compound semiconductor light-emitting element further includes a p-type AlₓGa_{y}N (where 0<x≦1 and 0≦y<1) electron blocking layer which is arranged between the p-type gallium nitride based compound semiconductor layer and the active layer. The p-type AlₓGa_{y}N (where 0<x≦1 and 0≦y<1) electron blocking layer is adjacent to the p-type gallium nitride based compound semiconductor layer. And the p-type AlₓGa_{y}N (where 0<x≦1 and 0≦y<1) electron blocking layer has a higher oxygen concentration than the p-type gallium nitride based compound semiconductor layer.

In yet another embodiment, the concentration of hydrogen included in the n-type gallium nitride based compound semiconductor layer and the active layer is less than 2.0×10¹⁷ cm⁻³.

In this particular embodiment, the concentration of hydrogen included in the n-type gallium nitride based compound semiconductor layer is equal to or lower than the concentration of hydrogen included in the active layer.

In yet another embodiment, the p-type gallium nitride based compound semiconductor layer has a thickness of 50 nm to 500 nm.

In yet another embodiment, the gallium nitride based compound semiconductor light-emitting element further includes a p-type contact layer which contacts with both an electrode and the p-type gallium nitride based compound semiconductor layer. The p-type contact layer includes magnesium at a concentration of at least 4.0×10¹⁹ cm⁻³ and has a thickness of 20 nm to 100 nm.

In yet another embodiment, the p-type gallium nitride based compound semiconductor layer is made of GaN.

A light source according to another embodiment of the present disclosure includes: a gallium nitride based compound semiconductor light-emitting element according to any of the embodiments described above; and a wavelength changing section which includes a phosphor that changes the wavelength of light emitted from the gallium nitride based compound semiconductor light-emitting element.

A method for fabricating a gallium nitride based compound semiconductor light-emitting element according to yet another embodiment of the present disclosure includes the steps of: forming an n-type gallium nitride based compound semiconductor layer; forming a p-type gallium nitride based compound semiconductor layer as an m-plane semiconductor layer; and forming an active layer as another m-plane semiconductor layer between the n- and p-type gallium nitride based compound semiconductor layers. The step of forming the p-type gallium nitride based compound semiconductor layer includes forming the p-type gallium nitride based compound semiconductor layer by adjusting the flow rate of a magnesium source gas so that the p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium.

In one embodiment, the step of forming the p-type gallium nitride based compound semiconductor layer includes controlling the concentrations of oxygen and magnesium in the p-type gallium nitride based compound semiconductor layer by adjusting respective flow rates of both the magnesium source gas and a gallium source gas.

In another embodiment, the step of forming the p-type gallium nitride based compound semiconductor layer includes setting the flow rate of the gallium source gas to fall within the range of 15 μmol/min to 110 μmol/min.

In still another embodiment, the step of forming the p-type gallium nitride based compound semiconductor layer includes setting the growth rate of the p-type gallium nitride based compound semiconductor layer to fall within the range of 4 nm/min to 28 nm/min.

Japanese Patent Publication No. 4375497 says that “if a gallium nitride based semiconductor region is provided on a semi- or non-polar plane and includes oxygen at a concentration of 5×10¹⁶ cm⁻³ or more, then the gallium nitride based semiconductor region would have a flattened surface morphology. The surface of the gallium nitride based semiconductor region also exhibits either semi-polarity or non-polarity depending on whether the principal surface of the substrate is a semi-polar plane or a non-polar plane. If the gallium nitride based semiconductor region included oxygen at a concentration of more than 5×10¹⁸ cm⁻³, then the crystal quality of the gallium nitride based semiconductor region would no longer be good enough”, and discloses a technique for making such a gallium nitride based semiconductor region to be provided on a semi- or non-polar plane include oxygen at a concentration falling within the range of 5×10¹⁶ cm⁻³ to 5×10¹⁸ cm⁻³. However, Japanese Patent Publication No. 4375497 is silent about how to prevent the diffusion of hydrogen, which is one of the objects of the present disclosure. Since Japanese Patent Publication No. 4375497 fails to suggest the relation between the respective concentrations of oxygen, Mg and hydrogen in a p-type layer at all and since the present disclosure does use the property of the m-plane growth, it should be difficult to come up with the idea of the present disclosure based on what is disclosed in Japanese Patent Publication No. 4375497. In addition, according to the present disclosure, addition of oxygen is controlled in quite a different way from what is taught in Japanese Patent Publication No. 4375497, as will be described later.

On the other hand, in order to deal with “the problem that even if every Mg atom introduced by doping turned into an acceptor, the carrier concentration (hole concentration) at room temperature will be lower than the Mg concentration by almost two digits, because the acceptor level of Mg in GaN is as deep as 200 meV”, Japanese Patent Publication No. 4305982 discovered that “if an Mg-doped GaN layer is grown by MOCVD process, the oxygen concentration varies according to the V/III ratio of the source gas used for the growing process, so does the carrier concentration accordingly” and discloses a method for controlling the V/III ratio in order to add oxygen to the p-type layer intentionally. However, Japanese Patent Publication N 4305982 fails to disclose how to prevent the diffusion of hydrogen, which is one of the objects of the present disclosure. Also, it is a phenomenon peculiar to a non-polar (10-10) m plane that hydrogen diffuses easily. That is to say, Japanese Patent Publication No. 4305982 that supposes that the crystals grow on a c plane and the present disclosure have totally different origins.

Moreover, although Japanese Patent Publication No. 4305982 says that the oxygen concentration is controlled by adjusting the V/III ratio, the oxygen concentration is controlled by a totally different method that utilizes the property of an m plane according to the manufacturing process of an embodiment of the present disclosure. The results of the experiments the present inventors carried out revealed that when the V/III ratio was increased by reducing the flow rate of trimethylgallium (TMG) to be supplied as a Ga source gas in the m-plane growing process, the oxygen concentration rather increased, contrary to the teaching of Japanese Patent Publication No. 4305982 about the c-plane growth. The present inventors also discovered via experiments that according to the c-plane growth, even if a p-type layer was deposited at the decreased V/Ill ratio of 6000 or less, the oxygen concentration was still less than the lower limit of SIMS detection and the presence of oxygen entered could not be confirmed effectively.

In an embodiment of the present disclosure, the V/III ratio may be set to be 10000 or more while the p-type layer is being grown.

Next, it will be described how to control the concentration of oxygen to be added to the p-type layer.

The present inventors invented a method for making full use of oxygen included as an impurity in bis-cyclopentadienyl magnesium (Cp₂Mg), which is a source material of Mg. The present inventors discovered via experiments that an m plane is a plane orientation in which oxygen is absorbed easily during the growing process in the first place. By paying special attention to this property, the present inventors came up an idea of using oxygen included as an impurity in Cp₂Mg which is a source material of Mg. As a result, the present inventors discovered that the concentration of oxygen in the p-type layer can be controlled by adjusting the flow rate of Cp₂Mg supplied. That is to say, if the flow rate of Cp₂Mg supplied is increased, the ratio of the oxygen concentration to the Mg concentration of the p-type layer can be raised. Conversely, if the flow rate of Cp₂Mg supplied is decreased, the ratio of the oxygen concentration to the Mg concentration of the p-type layer can be lowered.

However, if the flow rate of Cp₂Mg supplied is changed, not only the ratio of the oxygen concentration to the Mg concentration but also the Mg concentration of the p-type layer itself will naturally change, because Cp₂Mg is a source material of Mg. That is why the present inventors developed a method for controlling the respective concentrations of Mg and oxygen independently of each other by also adjusting the flow rate of a Ga source material that determines the growth rate of the p-type layer.

FIG. 8 shows how the oxygen concentrations of a p-type layer changes with its Mg concentration. Condition A (plotted with the solid circles ) shows the results obtained in a situation where the p-type layer was deposited while the flow rate of trimethylgallium (TMG), which is a Ga source material, is set to be 28 μmol/min. On the other hand, Condition B (plotted with the open circles ◯) shows the results obtained in a situation where the p-type layer was deposited while the flow rate of TMG is tripled to 84 μmol/min.

According to Condition B, the flow rate of TMG that determines the growth rate is increased to a value that is three times as high as that of Condition A. That is why the growth rate (of 21 nm/min) of the p-type layer of a sample that was made under Condition B is three times as high as the growth rate (of 7 nm/min) of the p-type layer of a sample that was made under Condition A. For that reason, to obtain p-type layers with the same Mg concentration, more Cp₂Mg needs to be supplied according to Condition B than when Condition A is adopted. For example, to obtain p-type layers each having an Mg concentration of 1.2 to 1.3×10¹⁹ cm⁻³, Cp₂Mg needs to be supplied at a flow rate of 0.43 μmol/min according to Condition A. According to Condition B, on the other hand, Cp₂Mg needs to be supplied at a flow rate of 0.65 μmol/min. As can be seen, even if their p-type layers have the same Mg concentration, Cp₂Mg needs to be supplied at different flow rates. Consequently, the concentrations of oxygen included as an impurity in Cp₂Mg become different from each other, and eventually the p-type layers come to have different oxygen concentrations, too.

For that reason, to obtain a p-type layer having intended Mg and oxygen concentrations, the flow rate of the Ga source material supplied also needs to be adjusted as well. The present inventors controlled the Mg and oxygen concentrations of the p-type layer in that way. Optionally, it is also an effective method to specify finely other additional parameters for adjusting the Mg and oxygen concentrations such as the growing temperature, growing pressure, atmosphere in the reaction furnace and concentration of oxygen that has entered as an impurity the Cp₂Mg source material itself. On the other hand, a p-type layer that has been grown by typical traditional c-plane growing process will have taken in oxygen less efficiently than the m-plane-growing p-type layer does. That is why it is very difficult to control the oxygen concentration accurately according to such a method.

According to the results shown in FIG. 8, if the Mg concentration of the p-type layer increases to go over 2.0×10¹⁹ cm⁻³ and reach the vicinity of 2.5×10¹⁹ cm⁻³, oxygen will be taken into the p-type layer in a different way from a situation where the Mg concentration of the p-type layer is less than 2.0×10¹⁹ cm⁻³ or 2.5×10¹⁹ cm⁻³. Also, if the Mg concentration is more than 2.0×10¹⁹ cm⁻³ or 2.5×10¹⁹ cm⁻³, the difference in oxygen concentration becomes less significant between Condition A and B. This result suggests that if the Mg concentration exceeds 2.0×10¹⁹ cm⁻³ or 2.5×10¹⁹ cm⁻³, oxygen will be taken in differently to make it difficult to control the ratio of the Mg concentration to the oxygen concentration within an appropriate range. That is why to achieve the effects of the present disclosure appropriately, the Mg concentration of the p-type layer is set to be suitably 2.5×10¹⁹ cm⁻³ or less, and more suitably 2.0×10¹⁹ cm⁻³ or less.

FIG. 9 shows the results of the experiments that the present inventors carried out.

As for samples of an m-plane-growing p-type layer including not only Mg but also oxygen, their Mg concentrations are plotted as the abscissas and their oxygen concentrations are plotted as the ordinates. The dotted line is a boundary indicating 5% of the Mg concentration and the solid line is a boundary indicating 15% of the Mg concentration. If the oxygen concentration of the p-type layer were less than 5% of the Mg concentration (as indicated by the open triangles Δ under the dotted line), hydrogen would diffuse from the p-type layer toward the active layer, thus decreasing the reliability of the element. If the traditional m-plane growing process is carried out under a standard condition, the oxygen concentration of the p-type layer typically becomes less than 5% of the Mg concentration and hydrogen will start to diffuse at a penetration length of 100 nm or more.

On the other hand, if the oxygen concentration were too high to be equal to or less than 15% of the Mg concentration (as indicated by the crosses X over the solid line), then the resistivity of the p-type layer would be more than 2 Ωcm to deteriorate the electrical characteristic of the p-type layer itself. Meanwhile, in a p-type layer including oxygen at a concentration that is 5% to 15% of the Mg concentration (as indicated by the open circles ◯ between the dotted and solid lines), diffusion of hydrogen can be prevented and the p-type layer can maintain good electrical characteristics, too.

The data shown in FIG. 9 is summarized in the following Table 2, which shows the Mg concentrations, oxygen concentrations, ratios of the oxygen concentration to the Mg concentration, hydrogen penetration lengths, and resistivities with respect to the data shown in FIG. 9. In Table 2, the open circle ◯ indicates samples in which the ratio of the oxygen concentration to the Mg concentration falls within the range of 5% to 15%. The open triangle Δ indicates samples in which the ratio of the oxygen concentration to the Mg concentration is less than 5%. And the cross X indicates samples in which the ratio of the oxygen concentration to the Mg concentration is more than 15%.

TABLE 2

| | | | | Hydrogen | | |
|---|---|---|---|---|---|---|
| | Mg | Oxygen | | penetration | | Classified |
| | concentration | concentration | Oxygen/Mg | length | Resistivity | as |
| \textcircled{1} | 2.5 × 10¹⁸ cm⁻³ | 2.0 × 10¹⁷ cm⁻³ | 8% | 40 nm | 1.8 Ωcm | ◯ |
| \textcircled{2} | 4.3 × 10¹⁸ cm⁻³ | 3.0 × 10¹⁷ cm⁻³ | 7% | 45 nm | 1.3 Ωcm | ◯ |
| \textcircled{3} | 5.0 × 10¹⁸ cm⁻³ | 2.5 × 10¹⁷ cm⁻³ | 5% | 55 nm | 1.1 Ωcm | ◯ |
| \textcircled{4} | 7.4 × 10¹⁸ cm⁻³ | 7.0 × 10¹⁷ cm⁻³ | 9% | 38 nm | 0.9 Ωcm | ◯ |
| \textcircled{5} | 9.3 × 10¹⁸ cm⁻³ | 1.3 × 10¹⁸ cm⁻³ | 14% | 32 nm | 1.9 Ωcm | ◯ |
| \textcircled{6} | 1.0 × 10¹⁹ cm⁻³ | 1.1 × 10¹⁸ cm⁻³ | 11% | 36 nm | 1.2 Ωcm | ◯ |
| \textcircled{7} | 1.2 × 10¹⁹ cm⁻³ | 6.0 × 10¹⁸ cm⁻³ | 5% | 57 nm | 0.9 Ωcm | ◯ |
| \textcircled{8} | 1.9 × 10¹⁹ cm⁻³ | 1.2 × 10¹⁸ cm⁻³ | 6% | 50 nm | 0.9 Ωcm | ◯ |
| \textcircled{9} | 2.5 × 10¹⁹ cm⁻³ | 2.1 × 10¹⁸ cm⁻³ | 8% | 43 nm | 1.0 Ωcm | ◯ |
| \textcircled{10} | 5.0 × 10¹⁸ cm⁻³ | 2.0 × 10¹⁷ cm⁻³ | 4% | 95 nm | 1.1 Ωcm | Δ |
| \textcircled{11} | 1.2 × 10¹⁹ cm⁻³ | 4.8 × 10¹⁷ cm⁻³ | 4% | 100 nm | 0.8 Ωcm | Δ |
| \textcircled{12} | 1.4 × 10¹⁹ cm⁻³ | 5.6 × 10¹⁷ cm⁻³ | 4% | 110 nm | 0.8 Ωcm | Δ |
| \textcircled{13} | 3.5 × 10¹⁸ cm⁻³ | 6.0 × 10¹⁷ cm⁻³ | 17% | 30 nm | 5.1 Ωcm | X |
| \textcircled{14} | 7.0 × 10¹⁸ cm⁻³ | 1.2 × 10¹⁸ cm⁻³ | 17% | 30 nm | 3.0 Ωcm | X |
| \textcircled{15} | 1.4 × 10¹⁹ cm⁻³ | 2.5 × 10¹⁸ cm⁻³ | 18% | 30 nm | 2.8 Ωcm | X |
| \textcircled{16} | 3.0 × 10¹⁹ cm⁻³ | 5.0 × 10¹⁸ cm⁻³ | 17% | 30 nm | 2.8 Ωcm | X |

To overcome the problem that hydrogen would diffuse from the p-type layer to reach the active layer even while a metallic material is being patterned to form an electrode after the crystals have grown or while the element is being driven, it is an effective measure to take to make the p-type layer include oxygen at an appropriate concentration.

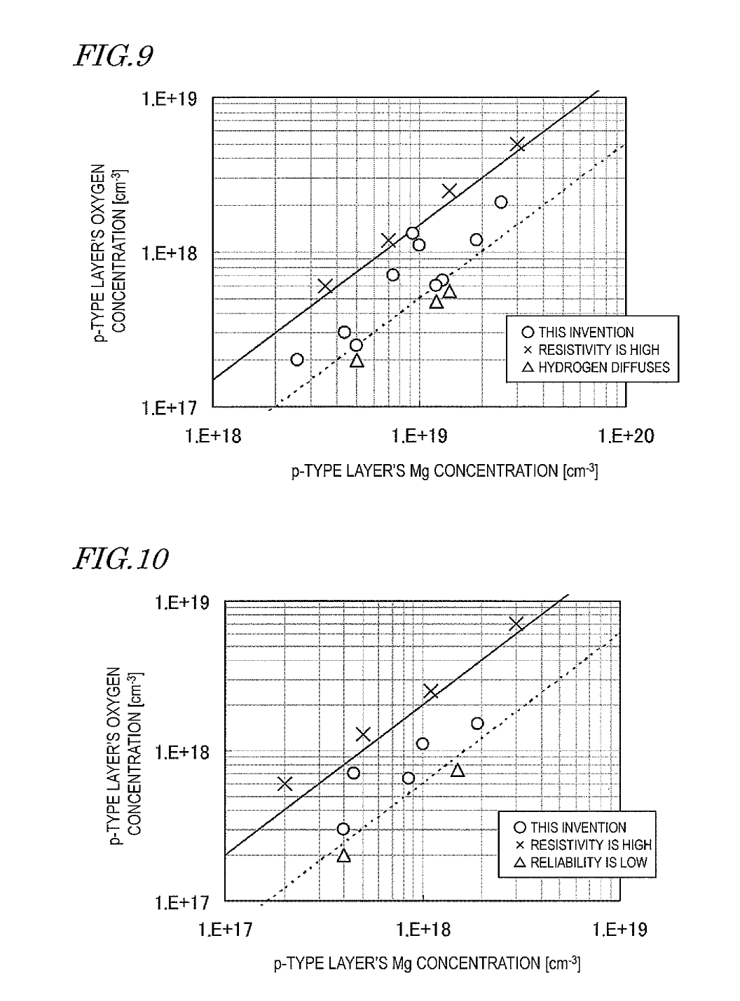

FIG. 10 shows the results of the experiments that the present inventors carried out. FIG. 10 shows how the oxygen concentration of an m-plane-growing p-type layer changes with its hydrogen concentration while the element is being driven. In FIG. 10, the hydrogen concentrations are plotted as the abscissas and the oxygen concentrations are plotted as the ordinates. The dotted line is a boundary indicating 60% of the hydrogen concentration and the solid line is a boundary indicating 200% of the hydrogen concentration.

The following Table 3 summarizes the hydrogen concentrations, oxygen concentrations, ratios of the oxygen concentration to the hydrogen concentration, whether hydrogen entered the active layer or not, and resistivities with respect to the data shown in FIG. 10. In Table 3, the open circle ◯ indicates samples in which the ratio of the oxygen concentration to the hydrogen concentration falls within the range of 60% to 200%. The open triangle Δ indicates samples in which the ratio of the oxygen concentration to the hydrogen concentration is less than 60%. And the cross X indicates samples in which the ratio of the oxygen concentration to the hydrogen concentration is more than 200%.

TABLE 3

| | Hydrogen | Oxygen | | Hydrogen | | Classified |
|---|---|---|---|---|---|---|
| | concentration | concentration | Oxygen/hydrogen | entered? | Resistivity | as |
| \textcircled{1} | 4.0 × 10¹⁷ cm⁻³ | 3.0 × 10¹⁷ cm⁻³ | 75% | NO | 1.6 Ωcm | ◯ |
| \textcircled{2} | 4.5 × 10¹⁷ cm⁻³ | 7.0 × 10¹⁷ cm⁻³ | 155% | NO | 1.8 Ωcm | ◯ |
| \textcircled{3} | 8.5 × 10¹⁷ cm⁻³ | 6.5 × 10¹⁷ cm⁻³ | 76% | NO | 1.1 Ωcm | ◯ |
| \textcircled{4} | 1.0 × 10¹⁸ cm⁻³ | 1.1 × 10¹⁸ cm⁻³ | 110% | NO | 1.2 Ωcm | ◯ |
| \textcircled{5} | 1.9 × 10¹⁸ cm⁻³ | 1.5 × 10¹⁸ cm⁻³ | 79% | NO | 1.1 Ωcm | ◯ |
| \textcircled{6} | 4.0 × 10¹⁷ cm⁻³ | 2.0 × 10¹⁷ cm⁻³ | 50% | YES | 1.4 Ωcm | Δ |
| \textcircled{7} | 1.5 × 10¹⁸ cm⁻³ | 7.5 × 10¹⁷ cm⁻³ | 50% | YES | 1.0 Ωcm | Δ |
| \textcircled{8} | 2.0 × 10¹⁷ cm⁻³ | 6.0 × 10¹⁸ cm⁻³ | 300% | NO | 4.9 Ωcm | X |
| \textcircled{9} | 5.0 × 10¹⁷ cm⁻³ | 1.3 × 10¹⁸ cm⁻³ | 260% | NO | 3.2 Ωcm | X |
| \textcircled{10} | 1.1 × 10¹⁸ cm⁻³ | 2.5 × 10¹⁸ cm⁻³ | 227% | NO | 2.2 Ωcm | X |
| \textcircled{11} | 3.0 × 10¹⁸ cm⁻³ | 7.0 × 10¹⁸ cm⁻³ | 230% | NO | 2.4 Ωcm | X |

If the oxygen concentration of the p-type layer were less than 60% of the hydrogen concentration (as indicated by the open triangles Δ under the dotted line shown in FIG. 10), hydrogen would diffuse from the p-type layer toward the active layer while the element is being driven and would decrease the reliability of the element. On the other hand, if the oxygen concentration were too high to be equal to or less than 200% of the hydrogen concentration (as indicated by the crosses X over the solid line shown in FIG. 10), then the resistivity of the p-type layer would be more than 2.0 Ωcm to deteriorate the electrical characteristic of the p-type layer itself. Meanwhile, in a p-type layer including oxygen at a concentration that is 60% to 200% of the hydrogen concentration (as indicated by the open circles ◯ between the dotted and solid lines shown in FIG. 10), diffusion of hydrogen while the element is being driven can be prevented and the p-type layer can maintain good electrical characteristics, too. That is why it is recommended that the oxygen concentration of the p-type layer be controlled to fall within the range of 60% to 200% of the hydrogen concentration.

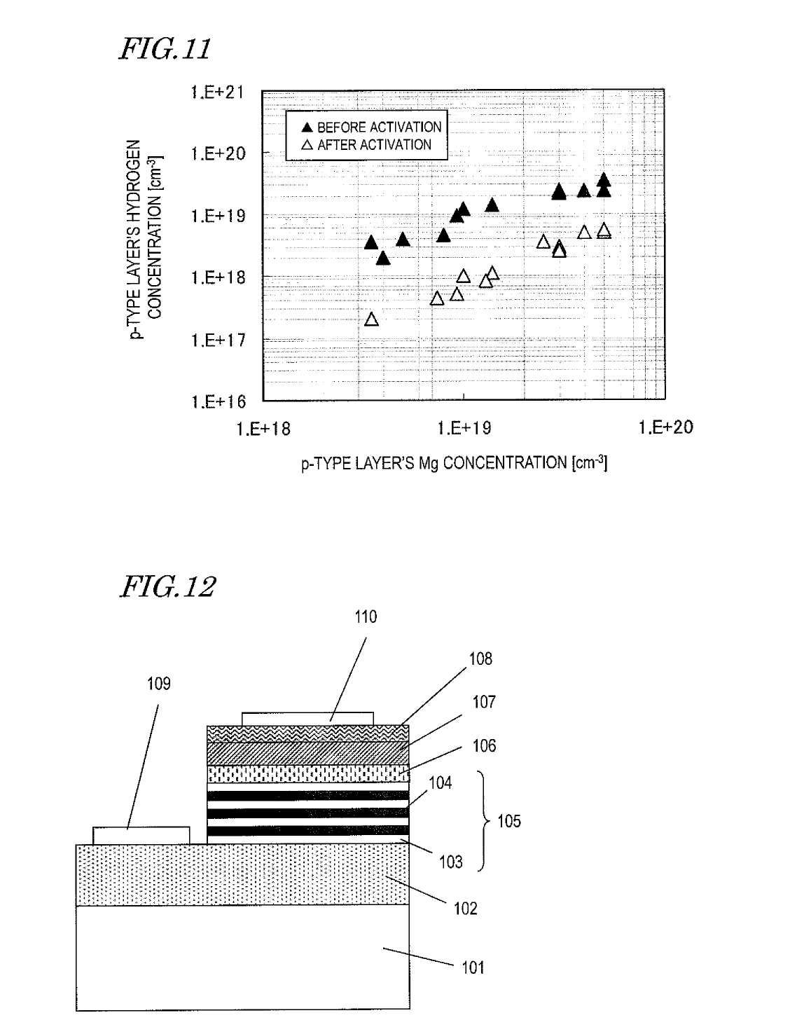

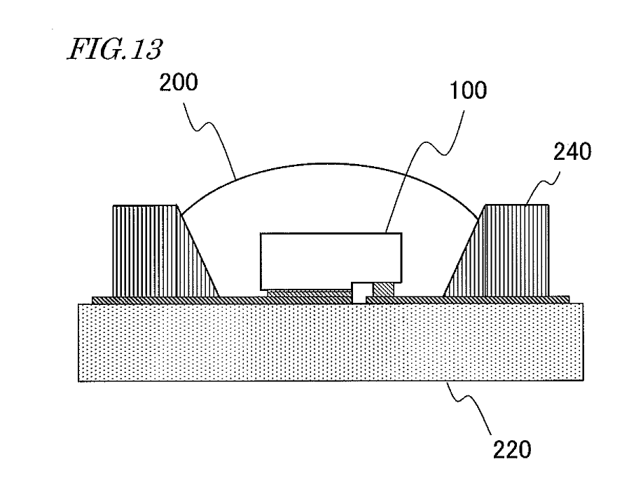

FIG. 11 shows how the hydrogen concentration changes before and after an m-plane-growing p-type layer is subjected to an annealing process. After the p-type layer has been subjected to the annealing process, the hydrogen concentration decreases to approximately 5 to 15% of the concentration of hydrogen that was included right after the p-type layer had been deposited. If the hydrogen concentration of the p-type layer that has been subjected to the annealing process is less than 2.0×10¹⁷ cm⁻³, it would be physically difficult for the concentration of hydrogen that has managed to enter the active layer to be more than 2.0×10¹⁷ cm⁻³ even if the hydrogen diffused and reached the active layer while the element is being driven. That is why the embodiment of the present disclosure is particularly effective if hydrogen included in the p-type layer has a concentration of 2.0×10¹⁷ cm⁻³ or more while the element is being driven.

Furthermore, as described above, once the Mg concentration exceeds 2.5×10¹⁹ cm⁻³ or 2.0×10¹⁹ cm⁻³, it becomes difficult to control the oxygen concentration within an appropriate range. According to the results shown in FIG. 11, when the Mg concentration is 2.5×10¹⁹ cm⁻³ or 2.0×10¹⁹ cm⁻³, the hydrogen concentration after the element has been subjected to the annealing process is approximately 2.5×10¹⁸ cm⁻³ or 2.0×10¹⁸ cm⁻³. That is why the oxygen concentration can be controlled easily if the hydrogen concentration of the p-type layer is 2.5×10¹⁸ cm⁻³ or less while the element is being driven. The oxygen concentration can be controlled even more easily if the hydrogen concentration of the p-type layer is 2.0×10¹⁸ cm⁻³ or less while the element is being driven. That is to say, this embodiment of the present disclosure is particularly effective if the concentration of hydrogen included in the p-type layer either falls within the range of 2.0×10¹⁷ cm⁻³ to 2.5×10¹⁸ cm⁻³ or equal to or lower than 2.0×10¹⁸ cm⁻³ while the element is being driven.

In the foregoing description, the element is supposed to go through an annealing process to give a general instance in which the hydrogen concentration of a p-type layer right after the element structure has been formed is different from the hydrogen concentration while the element is being driven. However, the p-type layer may be formed by any other method as long as hydrogen can be detached sufficiently from the p-type layer while the element is being driven. In fact, by modifying the process step of cooling the substrate in a crystal growing reaction furnace after the p-type layer had been deposited, the present inventors could decrease the concentration of hydrogen that entered as an impurity the p-type layer to such a degree as to realize good enough electrical characteristics even without performing the annealing process. The hydrogen concentration in such a situation is approximately the same as the hydrogen concentration right after the element has gone through the annealing process as shown in FIG. 11.

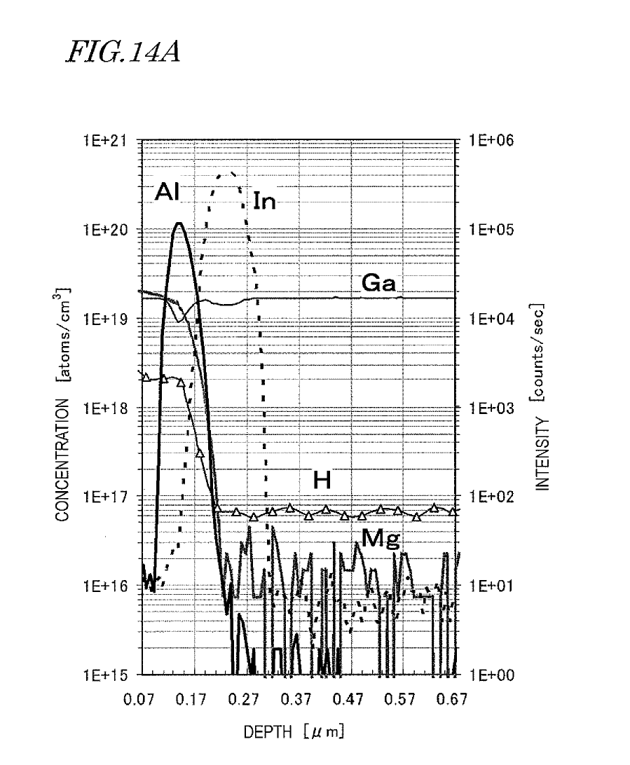

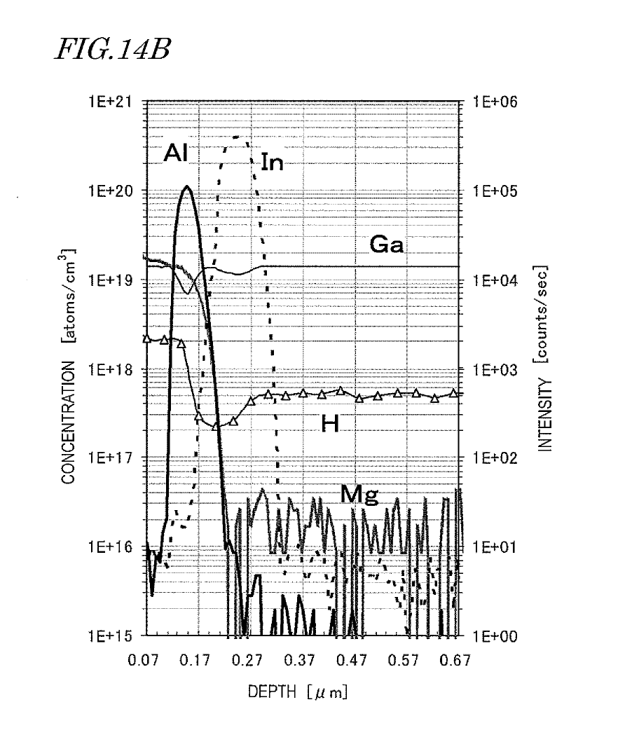

As described above, most of the hydrogen atoms that diffuse and reach the active layer come from the p-type layer. However, there is no denying that some hydrogen atoms could diffuse from an n-type layer. That is why to prevent those hydrogen atoms from diffusing toward the active layer, the concentration of hydrogen atoms that enter the n-type layer from the active layer is suitably 2.0×10¹⁷ cm⁻³ or less. Furthermore, the concentration of the hydrogen atoms that enter the n-type layer from the active layer is suitably uniform in the depth direction. By preventing not only the diffusion from the p-type layer but also the diffusion from the n-type layer, an active layer having a sufficiently low concentration of hydrogen atoms that have entered as an impurity can be obtained even while the element is being driven, and eventually a highly reliable element is realized. FIGS. 14A and 14B show the results of a SIMS analysis that was carried out on samples in which an n-type layer, an active layer, an undoped GaN spacer layer (having a thickness of approximately 30 nm) and a p-type layer were deposited in this order on a substrate and which were subjected to an annealing process. In the samples shown in FIGS. 14A and 14B, their n-type layers were grown under different conditions, and therefore, the concentrations of hydrogen that entered those n-type layers as an impurity were also different from each other. According to the results shown in FIG. 14A, the concentration of the hydrogen atoms that entered the n-type layer from the active layer was approximately 6×10¹⁶ cm⁻³ to 7×10¹⁶ cm⁻³ and substantially uniform in the depth direction. That is to say, it can be seen that the diffusion of the hydrogen atoms from the n-type layer toward the active layer could be minimized. Also, the sample shown in FIG. 14A turned out to be a reliable one for more than 1000 hours. In the sample shown in FIG. 14B, on the other hand, hydrogen atoms did diffuse from the n-type layer toward the active layer to cause the concentration of hydrogen in the active layer to fall within the range of 2×10¹⁷ cm⁻³ to 5×10¹⁷ cm⁻³. The radiant power output of the sample shown in FIG. 14B decreased to 70% or less in less than 1000 hours of operation. As can be seen from these results, by setting the hydrogen concentration of the n-type layer to be less than 2.0×10¹⁷ cm⁻³, not just can the diffusion of hydrogen toward the active layer be minimized but also can the reliability be increased.

The statement described above applies to not only when the growing plane is parallel to an m plane but also when the growing plane defines a tilt angle of 5 degrees or less with respect to the m plane. Thus, the “m-plane-growing semiconductor layer” according to the present disclosure may also refer to a semiconductor layer, of which the growing plane defines a tilt angle of 5 degrees or less with respect to an m plane.

### EMBODIMENT

Hereinafter, an embodiment of a gallium nitride based compound semiconductor light-emitting element and method for fabricating such an element according to the present disclosure will be described with reference to FIG. 12.

The gallium nitride based compound semiconductor light-emitting element of this embodiment includes an n-type gallium nitride based compound semiconductor layer 102, a p-type gallium nitride based compound semiconductor layer 107, and an active layer 105 which is arranged between the n- and p-type gallium nitride based compound semiconductor layers 102 and 107. The active layer 105 and the p-type gallium nitride based compound semiconductor layer 107 are m-plane semiconductor layers. The p-type gallium nitride based compound semiconductor layer 107 includes magnesium at a concentration of 2.0×10¹⁸ cm⁻³ to 2.5×10¹⁹ cm⁻³ and oxygen, of which the concentration is 5% to 15% of the concentration of the magnesium. Alternatively, the p-type gallium nitride based compound semiconductor layer 107 may have a magnesium concentration of 2.0×10¹⁸ cm⁻³ to 2.0×10¹⁹ cm⁻³.

The n-type gallium nitride based compound semiconductor layer 102 may be an n-GaN layer or an n-type AlₓGa_{y}In_{z}N (where 0≦x, y, z≦1 and x+y+z=1) layer. The p-type gallium nitride based compound semiconductor layer 107 may be a p-GaN layer or a p-type AlₓGa_{y}In_{z}N (where 0≦x, y, z≦1 and x+y+z=1) layer.

The p-type gallium nitride compound based semiconductor layer 107 includes hydrogen at a concentration of 2.0×10¹⁷ cm⁻³ to 2.5×10¹⁸ cm⁻³. Alternatively, the p-type gallium nitride based compound semiconductor layer 107 may have a hydrogen concentration of 2.0×10¹⁷ cm⁻³ to 2.0×10¹⁸ cm⁻³.

In the p-type gallium nitride based compound semiconductor layer 107, the concentration of oxygen included may be 60% to 200% of the concentration of hydrogen included. Optionally, an undoped spacer layer having a thickness of 100 nm or less may be interposed between the active layer 105 and the p-type gallium nitride based compound semiconductor layer 107. The active layer 105 has a GaN or InGaN multiple quantum well structure.

A p-AlGaN electron blocking layer 106 may be interposed between the active layer 105 and the p-type gallium nitride based compound semiconductor layer 107. The p-AlGaN electron blocking layer 106 may have a higher oxygen concentration than the p-type gallium nitride based compound semiconductor layer 106, for example. The concentration of hydrogen included in the n-type gallium nitride based compound semiconductor layer 102 and the active layer 105 is less than 2.0×10¹⁷ cm⁻³. The concentration of hydrogen included in the n-type gallium nitride based compound semiconductor layer 102 is equal to or lower than the concentration of hydrogen included in the active layer 105.

A crystal growing substrate 101 for use in this embodiment may be an m-plane GaN substrate, or an m-plane SiC substrate, of which the surface is covered with an m-plane GaN layer, or an r-plane or m-plane sapphire substrate, of which the surface is covered with an m-plane GaN layer. The most important point lies in that the active layer should be an m-plane nitride based semiconductor layer.

According to the present disclosure, the “m plane” may be a plane that tilts in a predetermined direction and defines a tilt angle of ±5 degrees or less with respect to an m plane that is not tilted. The growing plane of an actual m-plane semiconductor layer does not always have to be perfectly parallel to an m plane but may define a predetermined tilt angle with respect to the m plane. The tilt angle is defined by the angle that is formed between a normal line to the principal surface of the active layer and a normal line to the m plane. The absolute value of the tilt angle θ may be 5 degrees or less, and is suitably 1 degree or less, in the c-axis direction, and may be 5 degrees or less, and is suitably 1 degree or less, in the a-axis direction, too. Although the “m plane” is tilted overall with respect to the ideal m plane, the former plane actually consists of a number of steps, each of which is as thick as one to several atomic layers, and includes a huge number of m-plane regions, speaking microscopically. That is why planes that are tilted at an angle of 5 degrees or less (which is the absolute value) with respect to an m plane would have similar properties to those of the m plane. However, if the absolute value of the tilt angle θ is more than 5 degrees, the internal quantum efficiency could decrease due to a piezoelectric field. Nevertheless, even if the tilt angle θ is set to be 5 degrees, for example, the actual tilt angle θ could be different from 5 degrees by approximately ±1 degree due to some variation involved with the manufacturing process. It is difficult to totally eliminate such a manufacturing process induced variation and such a small angular difference as this would not diminish the effect of the present disclosure.

The gallium nitride-based compound semiconductor to form the GaN/InGaN multi-quantum well active layer 105 and other layers is deposited by MOCVD (metalorganic chemical vapor deposition) method. First of all, the substrate 101 is washed using a buffered hydrofluoric acid (BHF) solution, rinsed with water, and then dried sufficiently. The substrate 101 that has been washed in this manner is transported to the reaction chamber of an MOCVD system with its exposure to the air avoided as successfully as possible. Thereafter, with only ammonia (NH₃) gas supplied as a nitrogen source gas, the substrate is heated to 850 degrees Celsius to clean the surface of the substrate.

Next, with a trimethylgallium (TMG) gas or a triethylgallium (TEG) gas and a silane (SiH₄) gas supplied, the substrate is heated to about 1100 degrees Celsius to deposit an n-GaN layer 102. The silane gas is the source gas of Si as an n-type dopant.

Next, the supply of the SiH₄ gas is stopped and the temperature of the substrate is lowered to less than 800 degrees Celsius to form a GaN barrier layer 103. In addition, a trimethylindium (TMI) gas also starts to be supplied to deposit an In_{y}Ga_{1-y}N (where 0<y<1) well layer 104. In this embodiment, by alternately forming the GaN barrier layers 103 and In_{y}Ga_{1-y}N (where 0<y<1) well layers 104 in two or more cycles, a GaN/InGaN multi-quantum well active layer 105 that will emit light is formed. In this case, these layers are formed in two or more cycles, because the larger the number of the In_{y}Ga_{1-y}N (where 0<y<1) well layers 104, the more perfectly an excessive increase in the carrier density in the well layer can be avoided when the device is driven with a large current, the more significantly the number of carriers overflowing out of the active layer can be reduced, and eventually the better the performance of the element can be. The In_{y}Ga_{1-y}N (where 0<y<1) well layer 104 is suitably deposited by adjusting the growing time so that the layer will have a thickness of 2 nm to 20 nm. On the other hand, the GaN barrier layer 103 to separate the In_{y}Ga_{1-y}N (where 0<y<1) well layer 104 is suitably deposited by adjusting the growing time so that the layer will have a thickness of 7 nm to 40 nm. Optionally, the active layer 105 may have a multiple quantum well structure having any other configuration.

After the GaN/InGaN multi-quantum well active layer 105 has been deposited, the supply of the TMI gas is stopped and the hydrogen gas starts to be supplied again as a carrier gas, in addition to the nitrogen gas. Furthermore, the growing temperature is raised to the range of 850 degrees Celsius to 1000 degrees Celsius, and trimethylaluminum (TMA) and bis(cyclo-pentadienyl)magnesium (Cp₂Mg), which is a source gas of Mg as a p-type dopant, are supplied to form a p-AlGaN electron blocking layer 106.

Next, the supply of the TMA gas is stopped to deposit a p-GaN layer 107. Then, with the Cp₂Mg gas supplied at an increased flow rate, a p-GaN contact layer 108 is deposited right on the p-GaN layer 107. The p-GaN layer 108 will contact with a p-side electrode 110, which is described later. The p-GaN contact layer 108 may have a different Mg concentration from the p-GaN layer 107. The p-GaN contact layer 108 has a thickness of 20 nm to 100 nm, for example. Also, to reduce the contact resistance, the p-GaN contact layer 108 includes magnesium at a concentration of more than 2.0×10¹⁹ cm⁻³, and may even have a magnesium concentration of 4.0×10¹⁹ cm⁻³ or more.

When the p—GaN layer 107 is deposited, the flow rates of the TMG and Cp₂Mg gases supplied are adjusted so that the p-type layer has intended Mg and oxygen concentrations. Particularly, the flow rates of the TMG and Cp₂Mg gases supplied are suitably adjusted so that the oxygen concentration becomes 5% to 15% of the Mg concentration. If the Cp₂Mg gas is supplied at an increased rate, then the Mg and oxygen concentrations will both increase. On the other hand, if the Cp₂Mg gas is supplied at a decreased rate, then the Mg and oxygen concentrations will both decrease. The oxygen concentration depends only on the flow rate of the Cp₂Mg gas supplied. On the other hand, the Mg concentration is determined in conjunction with the flow rate of TMG gas that determines the growth rate of the GaN layer. Hereinafter, this point will be described in detail.

Generally speaking, if the flow rate of the TMG gas is increased, then the growth rate of the GaN layer rises. That is why if the flow rate of the TMG gas is increased with the flow rate of the Cp₂Mg gas fixed at a certain value, the Mg concentration tends to decrease. Also, if the flow rate of the Cp₂Mg gas is set to be higher than the ordinary value to make the oxygen concentration fall within the range in which the hydrogen diffusion can be suppressed and if the flow rate of the TMG gas is still set to be the ordinary value, the Mg concentration rises. However, if the growth rate of the p—GaN layer 107 is increased in this case by setting the flow rate of the TMG gas to be higher than the ordinary value, then the Mg concentration of the p-GaN layer 107 can be decreased relatively. As can be seen, if the flow rates of the Cp₂Mg and TMG gases are both adjusted appropriately in this manner, the Mg and oxygen concentrations of the p-GaN layer 107 can be adjusted. As a result, the targeted Mg and oxygen concentrations can be obtained. It should be noted that the growth rate of the p-GaN layer 107 also depends on the growing temperature and other process parameters and the type of the manufacturing system. The following is an exemplary set of specific growing process conditions that can be adopted to achieve the intended Mg and oxygen concentrations according to this embodiment:

Growing temperature: 930 degrees Celsius

TMG flow rate: 30 μmol/min

Growth rate: 7 nm/min

Cp₂Mg gas flow rate: 0.25 μmol/min

NH₃ gas flow rate: 0.33 μmol/min

Oxygen concentration: 6×10¹⁷ cm⁻³

Mg concentration: 9×10¹⁸ cm⁻³

Thickness of p-GaN layer 107: 200 nm

As described above, by setting the flow rate of the Cp₂Mg gas to be greater than this value, the oxygen concentration can be increased. Also, by setting the flow rate of the TMG gas to be greater than this value, the Mg concentration can be decreased. According to an embodiment of the present disclosure, when the p-GaN layer 107 is formed, the flow rate of the TMG gas may be set to fall within the range of 15 to 110 μmol/min and the growth rate may be set to fall within the range of 4 to 28 nm/min. It should be noted that the p-GaN layer 107 may have any arbitrary thickness that falls within the range of 50 nm to 500 nm, for example.

As for the p-AlGaN electron blocking layer 106, the oxygen concentration of the p-AlGaN electron blocking layer 106 may be set to be higher than that of the p-GaN layer 107 by the same method as what has already been described. By increasing the oxygen concentration of the p-AlGaN electron blocking layer 106, it is possible to prevent more effectively the hydrogen that has entered the p-GaN layer 107 from diffusing toward the active layer.

Optionally, an undoped spacer layer may be deposited to a thickness of 100 nm or less between the GaN/InGaN multiple quantum well active layer 105 and the p-AlGaN electron blocking layer 106. The undoped spacer layer is suitably made of GaN. With the Mg and oxygen concentrations adjusted within the ranges described above, even if hydrogen diffused from the p-GaN layer 107 while the element is being driven, the diffusion distance should be within 100 nm. That is why by providing the undoped GaN spacer layer, it is possible to prevent the hydrogen diffusing from reaching the GaN/InGaN multiple quantum well active layer 105. In that case, however, the drive voltage of the element should rise due to the insertion of the undoped GaN spacer layer.

After the substrate has been unloaded from the reaction chamber, only a predetermined region of the p—GaN contact layer 108, p-GaN layer 107, p-AlGaN electron blocking layer 106 and GaN/InGaN multiple quantum well active layer 105 is removed by photolithography and etching techniques, for example, to partially expose the n-GaN layer 102. In the region where the n-GaN layer 102 is exposed, an n-side electrode 109 comprised of Ti/Al layers, for example, is formed. As the p-side electrode 110, an electrode comprised of Pd/Pt layers may be used.

By performing these process steps, n-type and p-type carriers can be injected and a light-emitting element which emits light at an intended wavelength from the GaN/InGaN multiple quantum well active layer 105 that has been made by the manufacturing process of this embodiment can be obtained.

The gallium nitride based compound semiconductor light-emitting element of the embodiment described above may be used as a light source as it is. However, when combined with a wavelength changing section of a resin including a phosphor to change the wavelength, for example, the gallium nitride based compound semiconductor light-emitting element of this embodiment can be used effectively as a light source having a broadened wavelength range (e.g., as a white light source).

FIG. 13 is a schematic representation illustrating an example of such a white light source. The light source shown in FIG. 13 includes the light-emitting element 100 having the configuration shown in FIG. 12 and a resin layer 200 in which a phosphor (such as YAG (yttrium aluminum garnet)) to change the wavelength of the light emitted from the light-emitting element 100 into a longer wavelength is dispersed. The light-emitting element 100 has been mounted on a supporting member 220 on which an interconnect pattern has been formed. And on the supporting member 220, a reflective member 240 is arranged so as to surround the light-emitting element 100. The resin layer 200 is arranged to cover the light-emitting element 100.

An embodiment of the present disclosure provides a light-emitting element such as an LED having good electrical characteristics and reliability.

While the present disclosure has been described with respect to preferred embodiments thereof, it will be apparent to those skilled in the art that the disclosed disclosure may be modified in numerous ways and may assume many embodiments other than those specifically described above. Accordingly, it is intended by the appended claims to cover all modifications of the disclosure that fail within the true spirit and scope of the disclosure.

What is claimed is:

1. A gallium nitride based compound semiconductor light-emitting element comprising:
an n-type gallium nitride based compound semiconductor layer;
a p-type gallium nitride based compound semiconductor layer;
an active layer which is arranged between the n- and p-type gallium nitride based compound semiconductor layers; and
a p-type AlₓGa_{y}N (where 0<x≦1 and 0≦y<1) electron blocking layer which is arranged between the p-type gallium nitride based compound semiconductor layer and the active layer, wherein
the active layer and the p-type gallium nitride based compound semiconductor layer are m-plane semiconductor layers;
the p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium;
the p-type AlₓGa_{y}N (where 0<x≦1 and 0≦y<1) electron blocking layer is adjacent to the p-type gallium nitride based compound semiconductor layer; and
the p-type AlₓGa_{y}N (where 0<x≦1 and 0≦y<1) electron blocking layer has a higher oxygen concentration than the p-type gallium nitride based compound semiconductor layer.

2. The gallium nitride based compound semiconductor light-emitting element of claim 1, wherein the p-type gallium nitride based compound semiconductor layer further includes hydrogen at a concentration of 2.0×10¹⁷ cm⁻³ to 2.5×10¹⁸ cm⁻³.

3. The gallium nitride based compound semiconductor light-emitting element of claim 2, wherein in the p-type gallium nitride based compound semiconductor layer, the concentration of the oxygen included is 60% to 200% of the concentration of the hydrogen included.

4. The gallium nitride based compound semiconductor light-emitting element of claim 1, further comprising an undoped spacer layer which is arranged between the active layer and the p-type gallium nitride based compound semiconductor layer and which has a thickness of 100 nm or less.

5. The gallium nitride based compound semiconductor light-emitting element of claim 1, wherein the active layer has a multiple quantum well structure.

6. The gallium nitride based compound semiconductor light-emitting element of claim 1, wherein the concentration of hydrogen included in the n-type gallium nitride based compound semiconductor layer and the active layer is less than 2.0×10¹⁷ cm⁻³.

7. The gallium nitride based compound semiconductor light-emitting element of claim 6, wherein the concentration of hydrogen included in the n-type gallium nitride based compound semiconductor layer is equal to or lower than the concentration of hydrogen included in the active layer.

8. The gallium nitride based compound semiconductor light-emitting element of claim 1, wherein the p-type gallium nitride based compound semiconductor layer has a thickness of 50 nm to 500 nm.

9. The gallium nitride based compound semiconductor light-emitting element of claim 1, further comprising a p-type contact layer which contacts with both an electrode and the p-type gallium nitride based compound semiconductor layer,
wherein the p-type contact layer includes magnesium at a concentration of at least 4.0×10¹⁹ cm⁻³ and has a thickness of 20 nm to 100 nm.

10. The gallium nitride based compound semiconductor light-emitting element of claim 1, wherein the p-type gallium nitride based compound semiconductor layer is made of GaN.

11. A light source comprising:
the gallium nitride based compound semiconductor light-emitting element of claim 1; and
a wavelength changing section which includes a phosphor that changes the wavelength of light emitted from the gallium nitride based compound semiconductor light-emitting element.

12. A method for fabricating a gallium nitride based compound semiconductor light-emitting element, the method comprising the steps of:
forming an n-type gallium nitride based compound semiconductor layer;
forming a p-type gallium nitride based compound semiconductor layer as an m-plane semiconductor layer; and
forming an active layer as another m-plane semiconductor layer between the n- and p-type gallium nitride based compound semiconductor layers,
wherein the step of forming the p-type gallium nitride based compound semiconductor layer includes forming the p-type gallium nitride based compound semiconductor layer by adjusting the flow rate of a magnesium source gas so that the p-type gallium nitride based compound semiconductor layer includes magnesium at a concentration of 2.0×10¹⁸ cm⁻³ to 2.5×10¹⁹ cm⁻³ and oxygen, of which the concentration is 5% to 15% of the concentration of the magnesium.

13. The method of claim 12, wherein the step of forming the p-type gallium nitride based compound semiconductor layer includes controlling the concentrations of oxygen and magnesium in the p-type gallium nitride based compound semiconductor layer by adjusting respective flow rates of both the magnesium source gas and a gallium source gas.

14. The method of claim 12, wherein the step of forming the p-type gallium nitride based compound semiconductor layer includes setting the flow rate of the gallium source gas to fall within the range of 15 μmol/min to 110 μmol/min.

15. The method of claim 12, wherein the step of forming the p-type gallium nitride based compound semiconductor layer includes setting the growth rate of the p-type gallium nitride based compound semiconductor layer to fall within the range of 4 nm/min to 28 nm/min.
